(19) United States
(12) Patent Application Publication
(10) Pub. No.: US 2007/0246713 A1
(43) Pub. Date: Oct. 25, 2007

(54) LIGHT SOURCE AND METHOD FOR PRODUCING A LIGHT SOURCE

(75) Inventors: Jorg Arnold, Bern (CH); Adrian Dilo, Heidelberg (DE)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: IP2H AG

(21) Appl. No.: 11/736,478

(22) Filed: Apr. 17, 2007

Related U.S. Application Data
(63) Continuation of application No. PCT/DE05/01851, filed on Oct. 17, 2005.

(30) Foreign Application Priority Data
Oct. 17, 2004 (DE) 102004050711.2
Oct. 20, 2004 (DE) 102004051210.8
Nov. 15, 2004 (DE) 102004055091.3

(51) Int. Cl. H01L 33/00

(52) U.S. Cl. 257/79; 257/43; 257/431

(57) ABSTRACT

The invention relates to a light source comprising at least one p-n-junction which is formed by the arrangement of two suitable semi-conductor materials for the induced emission of light. Said light source is embodied and improved in such a manner that at least one of the semi-conductor materials is in the form of particles, such that a particularly large amount of light can be produced. The invention further relates to a method for producing said type of light source.

### CROSS-REFERENCE TO RELATED APPLICATIONS

This application is a continuation of PCT/DE2005/001851, filed Oct. 17, 2005, which claims priority to German Application Nos. 102004050711.2, filed Oct. 17, 2004, 102004051210.8, filed Oct. 20, 2004, and 102004055091.3, filed Nov. 15, 2004, which is hereby incorporated herein in its entirety by reference.

### BACKGROUND OF THE INVENTION

The present invention concerns a light source with at least one p-n junction formed by arrangement of two appropriate semiconductor materials for induced light emission. In addition, the present invention concerns a method for producing such a light source.

Light sources and methods for producing such light sources are known from practice and exist in different variants. For example, such light sources are known as luminescent lamps, especially light-emitting diodes (LEDs).

Such LEDs have been produced and sold since the 1970s. These are semiconductor components whose method of function is based mostly on a light-generating electron-hole recombination, which transitions from electron donor states to electron acceptor states that lie energetically in the band gap between the conduction band and the valence band in the vicinity of the band edges of the semiconductor. Light emission is induced by electric current flow (called feed current), whose electron-hole pairs are then separated, the electrons being raised to higher energy levels and falling back to lower energy levels with light emission and recombining with holes. In this process only a narrow lightwave band or monochromatic light is disadvantageously generated. The light emission of known LEDs lies in the range between the near-infrared and the near-ultraviolet.

The known LEDs are constructed by connecting two differently doped semiconductor materials in layered fashion, for example, by epitaxy with a sharp common interface. Semiconductor elements or semiconductor compounds from elements of groups IV-IV or III-IV are known, for example gallium phosphide, gallium arsenide-phosphorus, gallium-indium phosphide, gallium-aluminum arsenide or gallium nitride with, for example, tellurium, silicon, germanium, antimony, oxygen or selenium as n-doping atoms or electron donor atoms or with lithium, magnesium, nickel, chromium, iron, copper, tin, cadmium, manganese or germanium as p-doping atoms or electron acceptor atoms. The light-generating depletion layer or p-n junction of the semiconductor diode is formed around this sharp interface within the diffusion length of the free electrons. The semiconductor layers are applied to a solid support, which serves as a cooling element, for example, on a quartz wafer or sapphire wafer. The semiconductor layers are coated sandwich-like from the bottom and the top with a metal electrode layer corresponding to different geometric possibilities, the electrode layer generally consisting of gold. This type of structure is referred to as a chip. This construction is complicated and its production is disadvantageously more expensive in comparison with halogen lamps. High exciting current densities are necessary to produce relatively large amounts of light. For this purpose the conductor cross sections and therefore chip size must be kept as small as possible. Consequently, previous LEDs are point light sources. This again hampers heat removal from the chip, which is essential in order to avoid a significant lifetime reduction of the LED by heat-induced impurity diffusion or even heat destruction of the LED. In the known chip structures of LEDs it was therefore problematical that only smaller amounts of light can be generated in comparison with halogen lamps.

The underlying task of the invention is therefore to provide a light source and method for producing a light source of the type just mentioned, according to which a particularly large amount of light can be achieved with simple design means.

The aforementioned task is solved according to the invention by a light source with the features of claim 1. According to it the light source of the type just mentioned is configured and modified so that at least one of the semiconductor materials is present in the form of particles.

It was initially recognized according to the invention that light sources of the type just mentioned could also be produced without complicated chip structures that are demanding in manufacture. For this purpose, at least one of the semiconductor materials is formed as particles in a manner also according to the invention. In other words, the light source can be constructed from individual particles, the depletion layer being produced by the contact surface of two particles from the semiconductor materials differently doped as usual. Every two particles of differently doped semiconductor materials can form a p-n junction or light-emitting depletion layer in the contact site. The employed semiconductor materials need only have the property of being able to generate light-generating diode transitions or p-n junctions. A light source according to the invention can be constructed from a number of such particles and produced p-n junctions, from which a number of light-emitting areas are obtained. The design is then significantly simplified in comparison with previously known chip structures.

Consequently, a light source is provided with the light source according to the invention, according to which the particularly large amount of light can be achieved with simple design means.

Specifically, the particles could be present in the form of grains, particles and/or corpuscles. This is not a final listing of the small elements. Instead, particle is always understood to mean an element of any shape and strength, if it is not specially restricted. Not only the luminous, highly symmetric elements, like spheres, tetrahedra, cubes or polyhedra or voluminous nonsymmetric elements with a smooth surface, for example, potato-shaped elements are therefore involved, but so are elements that in one or more directions of their extent in comparison with another direction or other directions are very long and symmetric, like needles, thin disks, needle stars or leaf stars, or very nonsymmetric, like fibers or fiber tangles. These elements can have simply coherent surfaces, which in the conceived boundary process can therefore contract to a point, or not simply coherent surfaces, which can only contact to lines in the conceived boundary process. This would be a short or long tube or generally a torus with optionally several or even numerous hoops and/or holes. These elements or particles or grains could also be as bizarre as the mineral skeleton of algae or ice crystals.

To achieve good formation of a contact surface of the different semiconductor particles or grains, as an alternative, different particle shapes or grain shapes and different particle sizes or grain sizes can be chosen. Polygonal elements or grains or elements or grains with smooth surfaces or fractured surfaces have been shown to be particularly advantageous with good results with respect to producing p-n junctions, in which flat polygonal surfaces or flat fracture surfaces can lie against each other. The selected grain or element sizes have an effect on the statistical probability and statistical frequency with which the different semiconductor grains or elements suitably deposit against each other to form a light-emitting depletion layer. The choice of the grain or element shapes together with the grain or element sizes influences the formation of an effective current path cross section over the semiconductor material and therefore the light yield.

In addition to the previously used semiconductor materials, carbon in its different forms, for example, in the form of nanotubes, is also suitable, since it can also behave as a semiconductor, depending on its mode. Specifically, one of the semiconductor materials could be carbon, in which the carbon could be present preferably in the form of nanotubes.

The present invention furnishes a light source that can be constructed from a number or grains. The particles can then be mixed together to form several p-n junctions in the form of dust, powders, granulates or a suspension. The most homogeneous possible mixing of the components is then advantageous. Ultimately in the production method only the appropriate semiconductor materials must be mixed.

During use of suspensions it must kept in mind that the suspension liquid does not wet the semiconductor depletion layer surfaces and therefore prevent formation of a p-n junction. For this purpose the employed suspension could be produced from essentially a fully evaporating solvent. Such a solvent, however, should not dissolve the semiconductor materials.

Particles already having a p-n junction could be used with particular advantage. During use of a suspension, wetting of the semiconductor particles or semiconductor grains that prevents the p-n junctions could then be prevented, in particular. In other words, particles or grains that are already present as diode particles or diode grains with a p-n junction before mixing are used here.

To prepare such diode particles or diode grains the particles or grains already having a p-n junction could be coated particularly simply at least in areas with an appropriate semiconductor material. In other words, these diode particles or diode grains could already be produced in a previous production step in which the semiconductor particles or semiconductor grains could be coated with the second appropriate semiconductor material or with the second differently doped semiconductor material.

Coating by means of deposition from a gas phase or from a solution could be conducted particularly simply. The semiconductor particles or grains to be coated could then be coated only partially, i.e., only in areas on a partial surface.

As an alternative it would also be possible to produce macroscopic multilayers of the required semiconductor materials and then granulate or pulverize these multilayers in order to produce appropriate diode particles or diode grains. In other words, the particles already having a p-n junction could be present as granulated powder from a layer structure or multilayer of the appropriate semiconductor materials. In such granulates, powders or dusts appropriate grains or particles with a p-n depletion layer would already be present in very high probability.

To prepare a particularly stable light source the dusts, powders or granulates or the suspension could be arranged on a support. For this purpose a binder or adhesive layer could be arranged on the support in order to guarantee good adhesion of the dust, powders or granulates or the suspension. In both cases a powder mixture or suspension or the diode mass could be simply applied to the support.

As an alternative to a support already provided with a binder or adhesive layer, the dusts, powders, granulates or suspension could be mixed with a binder. Application of the binder or adhesive layer to the support could then be eliminated. In each case, the dusts, powders, granulates or the suspension could reliably adhere to the support.

With respect to reliable retention of electrical conductivity of the light source, the binder can be an electrically conducting substance. An electrically conducting polymer could then advantageously be used as binder.

With respect to particularly simple layout of the light source the support could have appropriate electrical contacts in order to guarantee power supply to the light source. The electrical contacts could be formed in particularly simple fashion by a metal foil, preferably gold foil applied or glued onto the support. As an alternative to this the electrical contacts could be formed in another simple manner by a metal pigment coating printed onto the support or by a metal deposited from a solution or a metal evaporated onto the support.

For reliable power supply of the light source the support could be formed from electrically nonconducting or poorly conducting material. With respect to good heat removal of the heat occurring during operation of the light source, the support could be formed from a well heat-conducting material. Forming the support from quartz, sapphire or diamond then works particularly well.

In another advantageous embodiment and with respect to particularly stable light sources the support can be designed tubular and the particles could be arranged in the support, in which case electrical contacts could preferably be provided on the ends of the support. In other words, a tubular support is filled with particles here.

In principle, the support could be designed monocrystalline or polycrystalline. This offers the advantage that such mono- or polycrystalline supports could already themselves have a p- or n-doping and therefore could form one of the semiconductor materials. In other words, a light source in which the support serves as one of the semiconductor materials and the applied particles could have a different appropriate doping as second semiconductor material is advantageous. If the support is p-doped, then the particles are n-doped and vice-versa.

In another particularly stable light source a support could be formed from two elements for sandwich-like enclosure of the particles. In other words, the particles could be enclosed sandwich-like by two flat elements of the support. In this variant doping of the elements of the support could then already be present in which the enclosed particles could then have a different appropriate doping.

In principle, in an already doped support the probability of formation of appropriate p-n junctions is higher than during exclusive use of particles for both semiconductor materials.

The particles could also be applied in a doped support by means of the above method. Either simple gluing or sintering of the particles onto the support then works.

The support could be appropriately shaped for adaptation to individual configuration requirements by deep drawing. Simple adjustment to different required geometries is possible here. This applies both for a simple structure and for a sandwich structure of the support.

In deposited or evaporated metal contacts, between every two contact strips or electrode strips a defined electrical voltage could be applied, which produces the necessary feed current that flows over the semiconductor particles or semiconductor grains which lie between two adjacent electrodes.

To adjust appropriate resistance conditions of the current path through the arrangement of semiconductor particles, the dusts, powders, granulates or the suspension could be mixed with a conducting material. In particularly simple fashion the conducting material could be a powdered or liquid polymer material or graphite or a metal granulate or powder or a metal suspension. The conducting material could then be formed from another appropriate semiconductor material.

In microscopically very small chosen particle or grain sizes, a significant part of the generated light is absorbed again within the light-generating LED layer. To eliminate this drawback, a light-conducting material could be mixed with the dust, powders, granulates or suspension. The light-conducting material in particularly simple fashion would have glass particles or light-conducting plastics. Such a light-conducting material could be added in powder or liquid form, for example, as a solution or suspension to the particle mixture so that a light guide effect on the LED surface is supported.

To summarize, in the light source according to the invention a mixture of dust, powders, granulates or suspensions could be generated in which the required and appropriate semiconductor materials, binders, conductivity agents, light guide agents and/or heat-conducting agents are added or mixed.

To prepare a light source with a particularly advantageous ignition behavior the semiconductor materials could be chosen so that different particle pairs could be produced with different light emission wavelengths. In other words, by the use or combination of different semiconductor materials and/or different doping in the light source according to the invention, different microscopic semiconductor particle pairs or semiconductor grain pairs or different elementary LEDs with different light emission wavelengths could be generated. The invention or the diode mass can therefore emit a color overlapping and in the limiting case of a very large number of very small semiconductor particle pairs or elementary diodes can produce and emit even a continuous light spectrum. The invention therefore permits the formation of light LEDs with a natural continuous spectrum and higher efficiency in contrast to previous white LEDs.

To implement a mechanically particularly stable light source, the particles on the support could be arranged next to each other by sintering. An almost polycrystalline structure can then be generated. In principle, polycrystalline compaction could lead to formation of a solid from the particles.

In another advantageous specific embodiment the light source could be inserted in incandescent bulbs or halogen bulbs instead of etched wire filaments. In other words, the light source could replace ordinary filaments. In an alternative embodiment the light source could even be designed as a fluorescent tube.

The aforementioned task is also solved by a method for producing a light source, especially a light source according to one of the claims 1 to 37. The light source has at least one p-n junction formed by arrangement of two appropriate semiconductor materials for induced light emission and is characterized by the fact that at least one of the semiconductor materials is used in the form of particles.

With respect to special advantages and properties of the method according to the invention, to avoid repetitions the previous description is referred to, according to which similar or identical advantages are described already in conjunction with the claimed light source.

In particularly advantageous fashion the particles could be mixed together to form several p-n junctions in the form of dusts, powders, granulates or a suspension. Particles that already have a p-n junction could then be used.

The particles already having a p-n junction could also advantageously be produced by coating at least in areas with an appropriate semiconductor material.

As an alternative the particles already having a p-n junction could be producers of granulate or powder from a layer structure or multilayer of appropriate semiconductor materials.

To implement the particularly light source the dusts, powders, granulates or suspension could be arranged in a carrier. In addition, semiconductor materials could be chosen so that different particle pairs with different light emission wavelengths can be generated. White LEDs, for example, can be produced by this.

To implement a particularly stable light source the particles can be arranged next to each other by sintering, in which an almost polycrystalline structure could be generated.

In principle, production of the light source according to the invention is very simple. Only the required and appropriate materials need be mixed powdered or in suspension, in which this diode mass then could merely be applied to the support provided with electrodes. Application of the electrodes could occur, for example, in the form of a printing method, by means of a dipping bath or by means of spray coating. The production method requires no highly complicated or expensive production processes or production investment, as is usual in the production of common LED chips. The particle mixture or diode mass can be applied both on flat and curved, on very small- and large-surface supports or surfaces. The present invention therefore guarantees formation of a luminescent element, light source or a lamp with a light emission space angle that can be stipulated arbitrarily, with a light emission surface size that can be stipulated arbitrarily and with a light spectrum that can be adjusted arbitrarily.

An alternative production method of the invention could be furnished by sintering the diode mass or a particle mixture. Support-free, solid light sources or luminescent elements with stipulated shapes, like thin plates or films, thin rods or wires or thin tubes could be generated. For illumination operation these need only be provided with electrical contacts on the ends bordering the current track. The necessary feed voltage can then be established arbitrarily according to the current track length together with the adjustable specific electrical resistance of the diode mass with a particle mixture. The invention therefore permits operation of diode light sources directly with 110 volt or 230 volt AC. Tungsten wire filaments of incandescent lamps or halogen lamps could therefore be advantageously replaced by diode wires or fluorescent tubes could be advantageously replaced by diode tubes.

There are now various possibilities of configuring and modifying the teachings of the present invention advantageously. For this purpose, the dependent claims are referred to, on the one hand, and the subsequent explanation of practical examples of the light source according to the invention with reference to the drawing on the other. In conjunction with explanation of the preferred practical examples of the light source according to the invention with reference to the drawing, preferred embodiments and modifications of the teachings are also explained in general. In the drawing

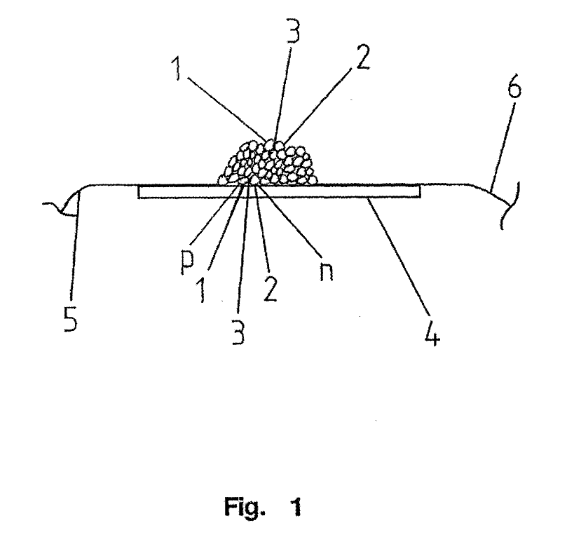

FIGS. 1 to 5 schematically depict practical examples of the light source according to the invention.

FIG. 1 schematically depicts a practical example of a light source according to the invention with at least one p-n junction 3 formed by the arrangement of two appropriate semiconductor materials 1 and 2 for induced light emission. With respect to a particularly large amount of light with simple design means, the semiconductor materials 1 and 2 are present in the form of particles. It is then possible to mix a number of particles from the appropriate semiconductor materials 1 and 2, in which case appropriate p-n junctions 3 can be formed on the contact sites of the particles

The particles of semiconductor materials 1 and 2 are arranged on a support 4 in order to form a stable light source. For electrical contacting of the light source electrical contacts 5 and 6 are applied to the support 4. Electrical contacts 5 and 6 are then formed by a metal foil applied to support 4. The support itself is made from a nonconducting material, specifically quartz.

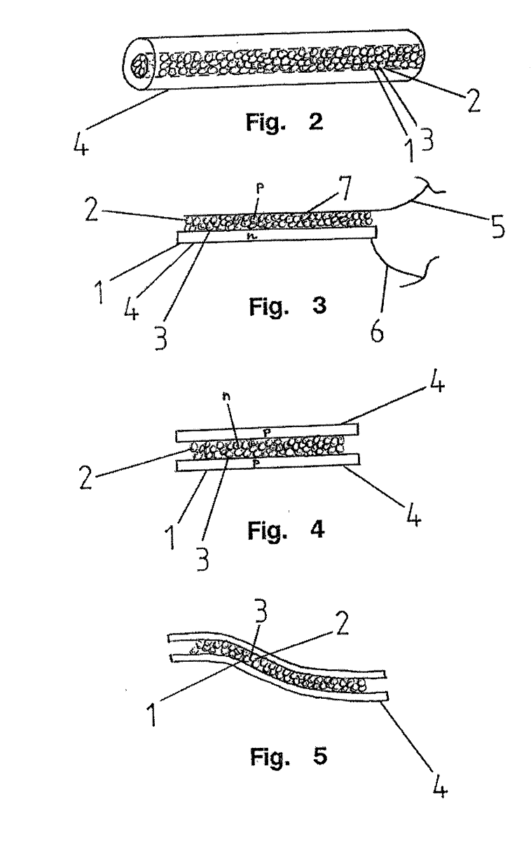

FIG. 2 schematically depicts another practical example of a light source according to the invention in which the support 4 is designed tube-like and filled with particles serving as semiconductor materials 1 and 2 to form the p-n junction 3. Electrical contacting can occur in appropriate fashion on the ends of the tubular support 4.

FIG. 3 schematically depicts a third practical example of a light source according to the invention in which one of the semiconductor materials 1 simultaneously serves as support and is formed by an n-doped monocrystalline or polycrystalline material. The p-doped material 2 is formed by particles. A p-n junction 3 is formed at the interface between support 4 and the particles. The electrical contacting occurs, on the one hand, via an electrical contact 5, which is connected to the metal foil 7, and, on the other hand, by an electrical contact 6, which is connected to the support 4.

FIG. 4 schematically depicts a fourth practical example of a light source according to the invention in which the semiconductor materials 1 and 2 here are formed by a support 4 and particles arranged between two elements of support 4. The particles are arranged sandwich-like between the flat support elements 4.

FIG. 5 schematically depicts a fifth practical example of a light source according to the invention with a shaped area of the light source. The practical example depicted in FIG. 5 is designed similarly to the practical example depicted in FIG. 4, but in which the support 4 has no doping and serves only as enclosure for semiconductor materials 1 and 2, which are formed as particles.

With respect to other advantageous embodiments of the light source according to the invention and the method for production of the light source according to the invention, to avoid repetitions, the general part of the description and the accompanying patent claims are referred to.

Finally, it is expressly pointed out that the previously described practical examples only serve to explain the claimed teachings but do not restrict them to these practical examples.

That which is claimed is:

1. Light source with at least one p-n junction formed by arrangement of two appropriate semiconductor materials for induced light emission, in which at least one of the semiconductor materials is present in the form of particles, the particles being mixed together to form several p-n junctions in the form of dust, powders, granulates or a suspension, and a conducting material being mixed with the dust, powders, granulates or a suspension,
characterized by the fact that the conducting material is a powder or liquid polymer material or graphite or a metal granulate or powder or a metal suspension.

2. Light source according to claim 1, characterized by the fact that the particles are present in the form of grains, particles and/or corpuscles.

3. Light source according to claim 1, characterized by the fact that the particles are polygonal elements or elements with smooth surfaces or fracture surfaces.

4. Light source according to claim 1, characterized by the fact that one of the semiconductor materials is carbon.

5. Light source according to claim 4, characterized by the fact that the carbon is present in the form of nanotubes.

6. Light source according to claim 1, characterized by the fact that the suspension is produced from an essentially fully evaporating solvent.

7. Light source according to claim 1, characterized by the fact that particles already having a p-n junction can be used.

8. Light source according to claim 7, characterized by the fact that the particles already having a p-n junction are coated at least in areas with an appropriate semiconductor material.

9. Light source according to claim 8, characterized by the fact that coating is carried out by deposition from a gas phase and a solution.

10. Light source according to claim 7, characterized by the fact that the particles already having a p-n junction are present as granulate or powder from a layer structure or layer mulitlayer of the appropriate semiconductor materials.

11. Light source according to claim 1, characterized by the fact that the dust, powders, granulates or suspension are arranged on a support.

12. Light source according to claim 11, characterized by the fact that a binder or adhesive layer is arranged on support.

13. Light source according to claim 1, characterized by the fact that the dust, powders, granulate or suspension are mixed with a binder.

14. Light source according to claim 12, characterized by the fact that the binder is an electrically conducting substance.

15. Light source according to claim 12, characterized by the fact that the binder is an electrically conducting polymer.

16. Light source according to claim 11, characterized by the fact that the support has appropriate electrical contacts.

17. Light source according to claim 16, characterized by the fact that the electrical contacts are formed by a metal foil, preferably gold foil applied or glued onto support.

18. Light source according to claim 16, characterized by the fact that the electrical contacts are formed by a metal pigment paint printed onto the support or by a metal deposited from solution onto the support or an evaporated metal.

19. Light source according to claim 11, characterized by the fact that the support is formed from electrically nonconducting or poorly conducting material.

20. Light source according to claim 11, characterized by the fact that the support is formed from a good heat-conducting material.

21. Light source according to claim 11, characterized by the fact that the support is formed from quartz, sapphire or diamond.

22. Light source according to claim 11, characterized by the fact that the support is designed tubular and the particles are arranged in the support, in which electrical contacts are preferably provided on the ends of support.

23. Light source according to claim 11, characterized by the fact that the support is designed monocrystalline.

24. Light source according to claim 11, characterized by the fact that the support is designed polycrystalline.

25. Light source according to claim 11, characterized by the fact that the support has a p- or n-doping and forms one of the semiconductor materials on account of this.

26. Light source according to claim 11, characterized by the fact that the support is formed from two elements for sandwich-like enclosure of the particles.

27. Light source according to claim 11, characterized by the fact that the particles are applied to support by sintering.

28. Light source according to claim 11, characterized by the fact that the support is appropriately formed by deep drawing.

29. Light source according to claim 1, characterized by the fact that dust, powders, granulates or suspension are mixed with a conducting material.

30. Light source according to claim 29, characterized by the fact that the light-conducting material has glass particles or light-conducting plastics.

31. Light source according to claim 1, characterized by the fact that the semiconductor materials are chosen so that different particle pairs with different light emission wavelengths can be produced.

32. Light source according to claim 1, characterized by the fact that the particles are arranged next to each other by sintering.

33. Light source according to claim 1, characterized by the fact that the light source is used in incandescent bulbs or halogen bulbs instead of heated wire filaments.

34. Light source according to one of the claim 1, characterized by the fact that the light source is designed as a fluorescent tube.

35. Method for production of a light source, with at least one p-n junction formed by arrangement of two appropriate semiconductor materials for induced light emission, in which at least one of the semiconductor materials is used in the form of particles, in which the particles are mixed together to form several p-n junctions in the form of dust, powders, granulates or a suspension and in which the conducting material is mixed with the dust, powders, granulates or suspension,
characterized by the fact that a powder or liquid polymer material or graphite or a metal granulate or powder or metal suspension is used as conducting material.

36. Method according to claim 35, characterized by the fact that particles already having a p-n junction are used.

37. Method according to claim 36, characterized by the fact that the particles already having a p-n junction are produced by coating at least in areas with an appropriate semiconductor material.

38. Method according to claim 36, characterized by the fact that the particles already having a p-n junction are produced as a granulate or powder from the layer structure or multilayer of appropriate semiconductor materials.

39. Method according to one of the claim 35, characterized by the fact that the dust, powders, granulates or suspension are arranged on a support.

40. Method according to one of the claim 35, characterized by the fact that semiconductor materials are chosen so that different particle pairs with different light emission wavelengths can be produced.

41. Method according to one of the claim 35, characterized by the fact that the particles are arranged next to each other by sintering.
